(19) United States
(12) Patent Application Publication
(10) Pub. No.: US 2020/0258991 A1
(43) Pub. Date: Aug. 13, 2020

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 16/726,631

(22) Filed: Dec. 24, 2019

(30) Foreign Application Priority Data
Feb. 8, 2019 (JP) 2019-022124

(51) Int. Cl. H01L 29/423; H01L 29/78; H01L 21/02; H01L 21/027; H01L 29/10; H01L 29/16; H01L 29/66; H01L 29/36

(52) U.S. Cl. CPC H01L 29/4236; H01L 29/7813; H01L 21/02529; H01L 21/0274; H01L 29/36; H01L 21/02579; H01L 29/1095; H01L 29/1608; H01L 29/66734; H01L 21/02576

(57) ABSTRACT

A semiconductor device includes an active region having: a first semiconductor layer of a first conductivity type provided on a semiconductor substrate, a second semiconductor layer of a second conductivity type, a first semiconductor region of the first conductivity type, a gate electrode embedded in a trench, an interlayer insulating film on the gate electrode, having an overhanging portion overhanging a part of the second semiconductor layer beyond the trench, a first electrode pad; and a gate electrode pad region having: the substrate, the first semiconductor layer, the second semiconductor layer, the first electrode pad, and a gate electrode pad. A distance from a contact area end, which is an end located furthest from the gate electrode pad in a contact area where the second semiconductor layer contacts the first electrode pad, to a second semiconductor layer end in a plan view is at least twice a width of the overhanging portion.

### CROSS REFERENCE TO RELATED APPLICATIONS

This application is based upon and claims the benefit of priority of the prior Japanese Patent Application No. 2019-022124, filed on Feb. 8, 2019, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Silicon (Si) is used as a material for power semiconductor devices that control high voltage and/or large current. There are several types of power semiconductor devices such as bipolar transistors, insulated gate bipolar transistors (IGBTs), and metal oxide semiconductor field effect transistors (MOSFETs). These devices are selectively used according to an intended purpose.

For example, bipolar transistors and IGBTs have high current density compared to MOSFETs, and can be adapted for large current but cannot be switched at high speeds. In particular, the limit of switching frequency is about several kHz for bipolar transistors and about several tens of kHz for IGBTs. On the other hand, power MOSFETs have low current density compared to bipolar transistors and IGBTs, and are difficult to adapt for large current but can be switched at high speeds up to about several MHz.

There is a strong demand in the market for large-current, high-speed power semiconductor devices. Thus, IGBTs and power MOSFETs have been intensively developed and improved, and the performance of power devices has substantially reached the theoretical limit determined by the material. In terms of power semiconductor devices, semiconductor materials to replace silicon have been investigated and silicon carbide (SiC) has been focused on as a semiconductor material enabling production (manufacture) of a next-generation power semiconductor device having low ON voltage, high-speed characteristics, and high-temperature characteristics.

Silicon carbide is chemically a very stable semiconductor material, has a wide bandgap of 3 eV, and can be used very stably as a semiconductor material even at high temperatures. Further, silicon carbide has a critical field strength that is at least ten times greater than the critical field strength of silicon and therefore, is expected to be a semiconductor material capable of sufficiently reducing ON resistance. Such characteristics of silicon carbide are shared by other wide bandgap semiconductor materials that have a wider bandgap than that of silicon such as, for example, gallium nitride (GaN). Therefore, use of a wide bandgap semiconductor material enables semiconductor devices of higher voltages.

In such a high-voltage semiconductor device that uses silicon carbide, to the extent that switching loss occurring with ON/OFF operation is reduced, a carrier frequency ten times that of a conventional semiconductor device that uses silicon may be applied in inverter applications. When a semiconductor device is used for high frequency applications, the temperature of the generated heat to which the chip is subjected increases, thereby affecting the reliability of the semiconductor device. In particular, when a bonding wire, as a wiring material that carries out electric potential of a front electrode, is bonded to a front electrode on a front upper portion of a substrate, and the semiconductor device is used under a high temperature, for example, 200 degrees C. or higher, adhesion between the front electrode and the bonding wire decreases, whereby reliability is adversely affected.

There are instances where a silicon carbide semiconductor device is used under a high temperature of 230 degrees C. or higher and therefore, a pin-shaped external terminal electrode may be soldered to the front electrode instead of the bonding wire. As a result, decreases in the adhesion between the front electrode and the pin electrode may be prevented.

FIG. 15 is a top view of a structure of a conventional silicon carbide semiconductor device. As depicted in FIG. 15, a semiconductor chip 150 has, at an outer periphery of an active region 140 through which main current passes, an edge termination region 141 that surrounds a periphery of the active region 140 and sustains breakdown voltage. In the active region 140, a gate electrode pad 122 electrically connected to a gate electrode via a gate poly-silicon electrode 133, and a source electrode pad 115 electrically connected to a source electrode are provided.

On the source electrode pad 115, a first protective film 121 is provided and on a plating film 116 in the first protective film 121, an external terminal electrode (not depicted) is provided via solder (not depicted). Similarly, on the gate electrode pad 122 as well, a first protective film (not depicted) and a plating film (not depicted) are provided and on the plating film, an external terminal electrode (not depicted) is provided via solder (not depicted).

FIG. 16 is a top view of another structure of a conventional silicon carbide semiconductor device. As depicted in FIG. 16, in this other structure of a conventional silicon carbide semiconductor device, gate resistance 134 is provided between the gate electrode pad 122 and the gate poly-silicon electrode 133. Even when silicon carbide semiconductor elements are used connected in parallel without connection of an external chip resistor and there is variation in characteristics between the silicon carbide semiconductor elements, uniform operation of the elements may be achieved due to the gate resistance 134.

FIG. 17 is a cross-sectional view of a structure of a portion the conventional silicon carbide semiconductor devices, cut along cutting line A-A′ in FIGS. 14 and 15. As depicted in FIG. 17, a trench MOSFET 150 is depicted as the conventional silicon carbide semiconductor devices. In the trench MOSFET 150, an n-type silicon carbide epitaxial layer 102 is deposited at a front surface of an n⁺-type silicon carbide substrate 101. In an upper portion of the n-type silicon carbide epitaxial layer 102, opposite a lower portion thereof facing the n⁺-type silicon carbide substrate 101, an n-type high-concentration region 106 is provided. Further, in the n-type high-concentration region 106, a second pt type base region 105 is selectively provided so as to underlie a bottom of a trench 118 overall. In a surface layer on a side of the n-type high-concentration region 106, opposite a side thereof facing toward the n⁺-type silicon carbide substrate 101, a first p⁺-type base region 104 is selectively provided.

Further, in the conventional trench MOSFET 150, a p-type base layer 103, an n⁺-type source region 107, a p⁺⁺-type contact region 108, a gate insulating film 109, a gate electrode 110, an interlayer insulating film 111, a source electrode 113, a rear electrode 114, the source electrode pad 115, and a the drain electrode pad (not depicted) are provided.

The source electrode pad 115 is formed by stacking, for example, a first TiN film 125, a first Ti film 126, a second TiN film 127, a second Ti film 128, and an Al alloy film 129. Further, at an upper portion the source electrode pad 115, the plating film 116, a solder 117, an external terminal electrode 119, the first protective film 121, and a second protective film 123 are provided.

Further, in a gate electrode pad region, the gate electrode pad 122 is provided electrically connected to the gate electrode 110 and insulated from the p⁺⁺-type contact region 108 by the interlayer insulating film 111.

FIG. 18 is a top view of a structure of a conventional silicon carbide semiconductor device in which a high-performance arithmetic circuit is provided. To further enhance reliability of a silicon carbide semiconductor device, a semiconductor device has been proposed in which a high-function region 103a such as a current sensing portion 137a, a temperature sensing portion 135a, and an over-voltage protecting portion (not depicted) is disposed on a single semiconductor substrate having a vertical MOSFET that is a main semiconductor element (for example, refer to Japanese Laid-Open Patent Publication No. 2017-79324). In case of a high-function structure, to stabilize and form the high-function region 103a, a region in which only the high-function region 103a is disposed is provided in the active region 140, separated from a unit cell of a main semiconductor element 115a and adjacent to the edge termination region 141. The active region 140 is a region through which main current passes when the main semiconductor element is ON. The edge termination region 141 is a region for mitigating electric field in the upper portion of the semiconductor substrate and sustaining breakdown voltage (withstand voltage). The breakdown voltage is a voltage limit at which no errant operation or destruction of an element occurs.

In the current sensing portion 137a, an external terminal electrode for current detection is provided. Current detection involves connecting external resistors between the external terminal electrode for current detection and the source electrode in the active region and detecting a potential difference between the external resistors to obtain a current value.

FIG. 19 is a top view of another structure of a conventional silicon carbide semiconductor device in which a high-performance arithmetic circuit is provided. As depicted in FIG. 19, in this other structure of the conventional silicon carbide semiconductor device, the gate resistance 134 is provided between the gate electrode pad 122 and the gate poly-silicon electrode 133.

FIG. 20 is a cross-sectional view of a structure of a portion, cut along cutting line B-B′ in FIGS. 18 and 19, of the conventional silicon carbide semiconductor device in which a high-performance arithmetic circuit is provided. In FIG. 20, a structure above (positive direction along z-axis) the p⁺⁺-type contact region 108 is not depicted. As depicted in FIG. 19, a p-type silicon carbide epitaxial layer 103 is provided in the n-type silicon carbide epitaxial layer 102 in a gate electrode pad region 122a, the temperature sensing portion 135a, and the current sensing portion 137a. The p-type base layer 103 in the gate electrode pad region 122a, the temperature sensing portion 135a, and the current sensing portion 137a is the p-type base layer 103 of the main semiconductor element 115a and in the current sensing portion 137a, an active region 137b of the current sensing portion is between the p-type base layers 103.

Further, in the gate electrode pad region 122a, the temperature sensing portion 135a, and the current sensing portion 137a, as depicted in FIG. 20, the p-type base layer 103 of each has a predetermined spacing.

### SUMMARY OF THE INVENTION

According to an embodiment of the invention, a semiconductor device includes an active region through which a main current passes during an ON state, the active region being configured by a MOS structure, the MOS structure including: a semiconductor substrate of a first conductivity type, having a front surface and a rear surface opposite to the front surface; a first semiconductor layer of the first conductivity type, provided on the front surface of the semiconductor substrate, the first semiconductor layer having a first side facing the semiconductor substrate and a second side opposite to the first side, an impurity concentration of the first semiconductor layer being lower than an impurity concentration of the semiconductor substrate; a second semiconductor layer of a second conductivity type, provided at a surface on the second side of the first semiconductor layer, the second semiconductor layer having a first side facing the semiconductor substrate and a second side opposite to the first side; a first semiconductor region of the first conductivity type, selectively provided in a surface layer on the second side of the second semiconductor layer; a trench that penetrates the first semiconductor region and the second semiconductor layer, and reaches the first semiconductor layer; a gate electrode provided in the trench, via a gate insulating film; an interlayer insulating film provided on the gate electrode, the interlayer insulating film having an overhanging portion overhanging a part of the second semiconductor layer beyond the trench; a first electrode provided on a surface of the second semiconductor layer and a surface of the first semiconductor region; a first electrode pad provided on a surface of the first electrode and being electrically connected to the first electrode; and a second electrode provided on the rear surface of the semiconductor substrate; and a gate electrode pad region including: the semiconductor substrate; the first semiconductor layer; the second semiconductor layer; the first electrode pad selectively provided on a surface of the second semiconductor layer; the interlayer insulating film selectively provided on a surface of the second semiconductor layer; and a gate electrode pad electrically connected to the gate electrode, the gate electrode pad being selectively provided at a surface on the second side of the second semiconductor layer, via the interlayer insulating film. In the gate electrode pad region, a distance from a contact area end of a contact area where the first electrode pad and the second semiconductor layer contact each other, to a second semiconductor layer end of the second semiconductor layer in a plan view of the semiconductor device is at least two times a width of the overhanging portion of the interlayer insulating film, the contact area end being an end located furthest in the contact area from the gate electrode pad, the second semiconductor layer end being an end located furthest in the second semiconductor layer from the gate electrode pad.

In the embodiment, the distance from the portion where the distance from the contact area end to the second semiconductor layer end is ten to twenty times the width of the overhanging portion of the interlayer insulating film.

In the embodiment, the second semiconductor layer includes a plurality of second semiconductor layer regions, one of the second semiconductor regions being the second semiconductor layer of the active region, the semiconductor device further including: a current detection region configured by the MOS structure and sharing the semiconductor substrate and the first semiconductor layer with the active region, the current detection region including another one of the second semiconductor layer regions disposed separated from the one of the second semiconductor layer regions of the active region by a first predetermined interval; and a temperature detection region sharing the semiconductor substrate and the first semiconductor layer with the active region, the temperature detection region including yet another one of the second semiconductor layer regions disposed separated from the one of the second semiconductor layer regions of the active region by a second predetermined interval. In the current detection region and in the temperature detection region, each length of a contact area where the first electrode pad and the second semiconductor layer contact each other in the plan view is at least two times a width of the overhanging portion of the interlayer insulating film.

In the embodiment, in the current detection region and in the temperature detection region, said each length of the contact area is at least equal to but less than twenty times the width of the overhanging portion of the interlayer insulating film.

According to another embodiment of the invention, a method of manufacturing a semiconductor device having an active region having a MOS structure through which a main current passes during an ON state and a gate electrode pad region, includes forming a first semiconductor layer of a first conductivity type on a semiconductor substrate of the first conductivity type, the semiconductor substrate having a front surface and a rear surface opposite to the front surface, the first semiconductor layer having a first side facing the semiconductor substrate and a second side opposite to the first side, an impurity concentration of the first semiconductor layer being lower than an impurity concentration of the semiconductor substrate; forming a second semiconductor layer of a second conductivity type at a surface on the second side of the first semiconductor layer, the second semiconductor layer having a first side facing the semiconductor substrate and a second side opposite to the first side; selectively forming a first semiconductor region of the first conductivity type in a surface layer on the second side of the second semiconductor layer; forming a trench that penetrates the first semiconductor region and the second semiconductor layer, and reaches the first semiconductor layer; forming a gate electrode in the trench, via a gate insulating film; forming on the gate electrode an interlayer insulating film to have an overhanging portion overhanging a part of the second semiconductor layer beyond the trench; forming a first electrode on a surface of the second semiconductor layer and a surface of the first semiconductor region; forming a first electrode pad on a surface of the first electrode and a surface of the second semiconductor layer, the first electrode pad being electrically connected to the first electrode; forming a second electrode on the rear surface of the semiconductor substrate; and selectively forming a gate electrode pad at a surface on the second side of the second semiconductor layer, via the interlayer insulating film, the gate electrode pad electrically connected to the gate electrode, wherein in the gate electrode pad region, a distance from a contact area end of a contact area where the first electrode pad and the second semiconductor layer contact each other, to a second semiconductor layer end of the second semiconductor layer in a plan view of the semiconductor device is at least two times a width of the overhanging portion of the interlayer insulating film, the contact area end being an end located furthest in the contact area from the gate electrode pad, the second semiconductor layer end being an end located furthest in the second semiconductor layer from the gate electrode pad.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view of a structure of a silicon carbide semiconductor device according to a first embodiment.

FIG. 2 is a cross-sectional view of a structure of a portion of the silicon carbide semiconductor device according to the first embodiment, cut along cutting line A-A′ in FIG. 1.

FIG. 3 is a top view of another structure of the silicon carbide semiconductor device according to the first embodiment.

FIG. 4 is a graph depicting relative values of interrupting current of a conventional silicon carbide semiconductor device and the silicon carbide semiconductor device according to the first embodiment.

FIG. 5 is a cross-sectional view of the silicon carbide semiconductor device according to the first embodiment during manufacture.

FIG. 6 is a cross-sectional view of the silicon carbide semiconductor device according to the first embodiment during manufacture.

FIG. 7 is a cross-sectional view of the silicon carbide semiconductor device according to the first embodiment during manufacture.

FIG. 8 is a cross-sectional view of the silicon carbide semiconductor device according to the first embodiment during manufacture.

FIG. 9 is a cross-sectional view of the silicon carbide semiconductor device according to the first embodiment during manufacture.

FIG. 10 is a cross-sectional view of the silicon carbide semiconductor device according to the first embodiment during manufacture.

FIG. 11 is a top view of a structure of the silicon carbide semiconductor device according to a second embodiment.

FIG. 12 is a cross-sectional view of a structure of a portion of the silicon carbide semiconductor device according to the second embodiment, along cutting line A-A′ in FIG. 11.

FIG. 13 is a cross-sectional view of a structure of a portion of the silicon carbide semiconductor device according to the second embodiment, along cutting line B-B′ in FIG. 11.

FIG. 14 is a top view of another structure of the silicon carbide semiconductor device according to the second embodiment.

FIG. 15 is a top view of a structure of a conventional silicon carbide semiconductor device.

FIG. 16 is a top view of another structure of a conventional silicon carbide semiconductor device.

FIG. 17 is a cross-sectional view of a structure of a portion the conventional silicon carbide semiconductor devices, cut along cutting line A-A′ in FIGS. 14 and 15.

FIG. 18 is a top view of a structure of a conventional silicon carbide semiconductor device in which a high-performance arithmetic circuit is provided.

FIG. 19 is a top view of another structure of a conventional silicon carbide semiconductor device in which a high-performance arithmetic circuit is provided.

FIG. 20 is a cross-sectional view of a structure of a portion, cut along cutting line B-B′ in FIGS. 18 and 19, of the conventional silicon carbide semiconductor device in which a high-performance arithmetic circuit is provided.

### DETAILED DESCRIPTION OF THE INVENTION

First, problems associated with the conventional techniques will be described. The vertical MOSFET having the conventional structure has built therein as a body diode between a source and a drain, a built-in pn diode configured by the p-type base region 103, the n-type high-concentration region 106, and the n-type silicon carbide epitaxial layer 102. The built-in pn diode may be operated by application of high electric potential to the source electrode 113, and current flows in a direction from the p⁺⁺-type contact region 108, through the p-type base region 103, the n-type high-concentration region 106 and the n-type silicon carbide epitaxial layer 102, to the n⁺-type silicon carbide substrate 101.

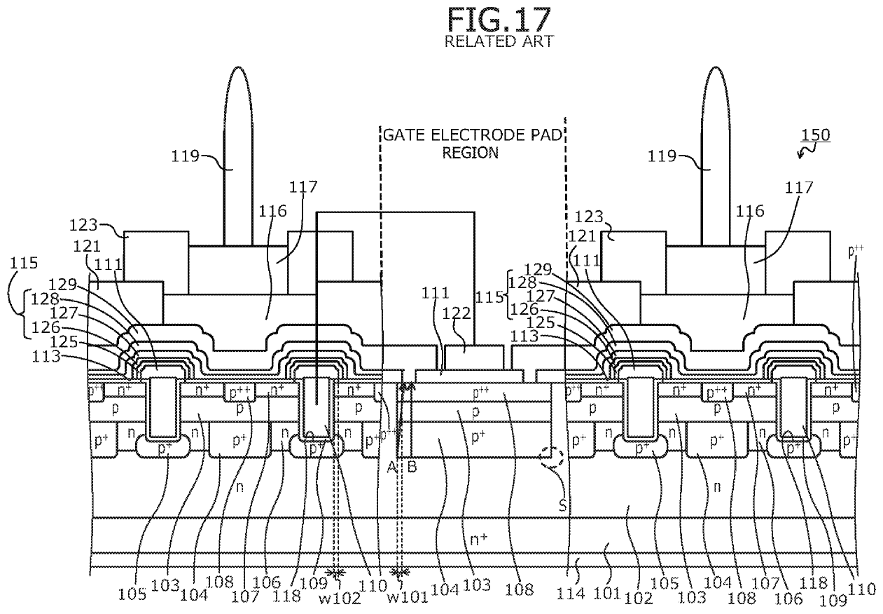

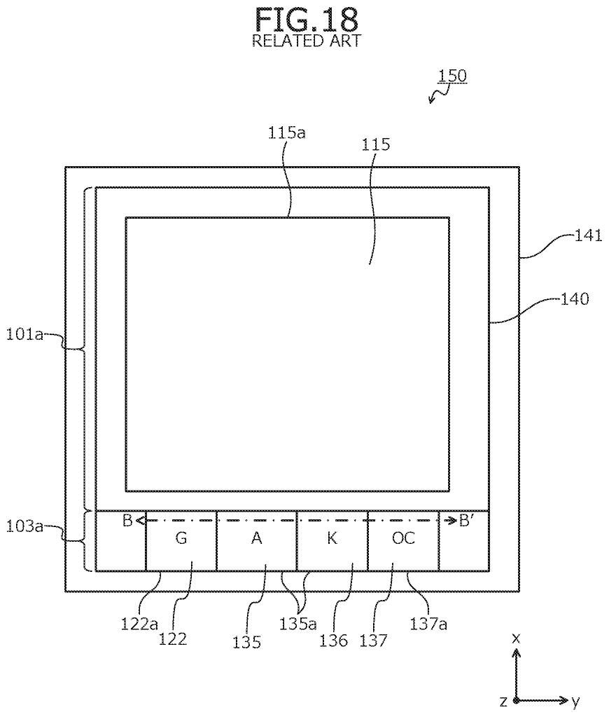

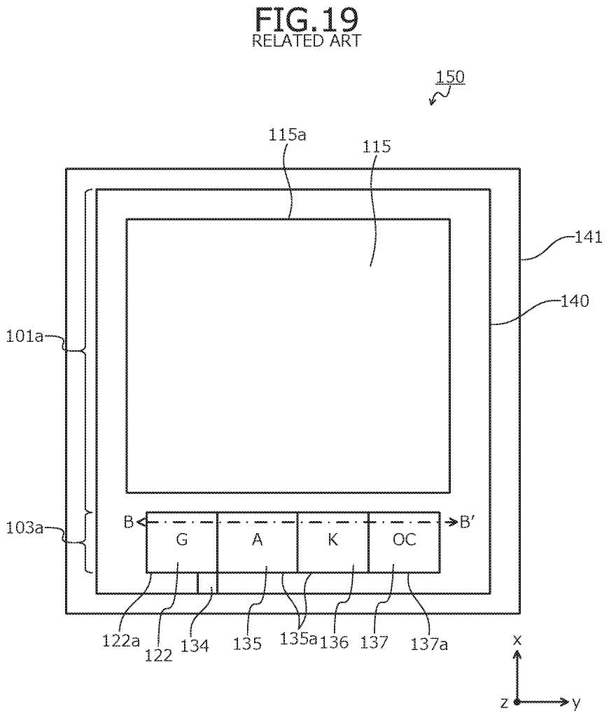

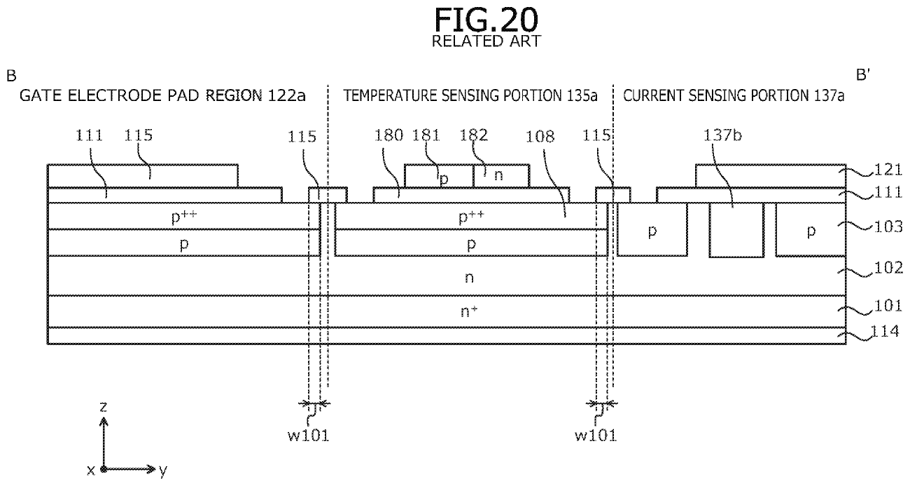

In the gate electrode pad region as well, a built-in diode is formed configured by an n-type semiconductor substrate and a p-type semiconductor region, functions as a diode, and current is energized. Problems arise in that when the built-in diode turns ON/OFF, carriers concentrate at a peripheral portion (for example, a region S in FIG. 17) of a p-type semiconductor region of a gate pad region, interrupting current during switching may decrease, and current capacity during reverse recovery may decrease.

Embodiments of a silicon carbide semiconductor device and a method of manufacturing a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described. Further, in the present description, when Miller indices are described, “−” means a bar added to an index immediately after the “−”, and a negative index is expressed by prefixing “−” to the index.

A semiconductor device according to the present invention is configured using a wide bandgap semiconductor. In the embodiments, a silicon carbide semiconductor device fabricated using, for example, silicon carbide (SiC) as a wide bandgap semiconductor will be described taking a MOSFET as an example.

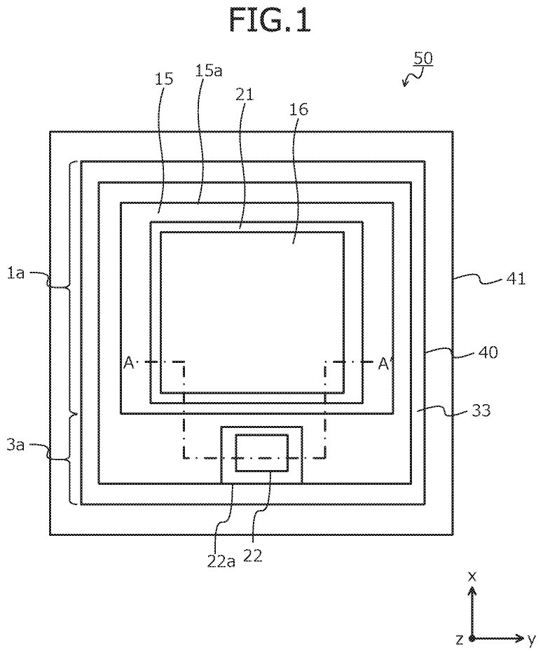

FIG. 1 is a top view of a structure of a silicon carbide semiconductor device according to a first embodiment. As depicted in FIG. 1, a semiconductor chip 50 includes an edge termination region 41 that surrounds a periphery of an active region 40 and sustains breakdown voltage, the edge termination region 41 being provided at an outer periphery of the active region 40 through which main current passes.

As depicted in FIG. 1, the semiconductor chip 50 has a main semiconductor element 15a and a gate electrode pad region 22a on a single semiconductor substrate containing silicon carbide. The main semiconductor element 15a is a vertical MOSFET through which drift current passes in a vertical direction (depth direction z of semiconductor substrate) in an ON state, the main semiconductor element 15a being configured by plural unit cells (functional units: not depicted) disposed adjacently to each other and performing a main operation.

The main semiconductor element 15a is provided in an effective region (region functioning as a MOS gate) la of the active region 40. The effective region 1a of the active region 40 is a region through which a main current passes when the main semiconductor element 15a is ON, and a periphery thereof is surrounded by the edge termination region 41. In the effective region 1a of the active region 40, a source electrode pad (first electrode pad) 15 of the main semiconductor element 15a is provided on a front surface of the semiconductor substrate. The source electrode pad 15, for example, has a rectangular planar shape and, for example, substantially covers the effective region 1a of the active region 40 entirely.

The edge termination region 41 is a region between the active region 40 and a chip side surface, and is a region for mitigating electric field a front surface side of the semiconductor substrate and sustaining breakdown voltage (withstand voltage). In the edge termination region 41, for example, a breakdown voltage structure (not depicted) such as a p-type region configuring a guard ring or a junction termination extension (JTE) structure, a field plate, a RESURF, etc. is disposed. The breakdown voltage is a limit voltage at which no errant element operation or destruction of an element occurs.

Further, at the gate electrode pad region 22a, the gate electrode pad 22 is provided. The gate electrode pad 22, for example, has a substantially rectangular planar shape.

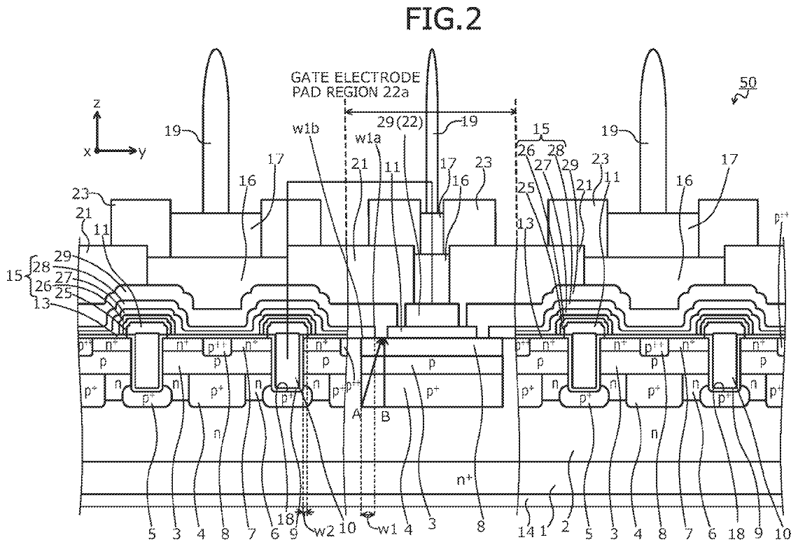

FIG. 2 is a cross-sectional view of a structure of a portion of the silicon carbide semiconductor device according to the first embodiment, cut along cutting line A-A′ in FIG. 1. FIG. 2 depicts a cross-sectional view of a structure from a portion of the effective region 1a of the active region 40 depicted in FIG. 1, through the gate electrode pad region 22a, to another portion of the effective region 1a, along cutting line A-A′.

As depicted in FIG. 2, in the semiconductor chip 50 of the silicon carbide semiconductor device according to the embodiment, an n-type silicon carbide epitaxial layer (first semiconductor layer of a first conductivity type) 2 is deposited on a first main surface (front surface), for example, a (0001) plane (Si-face), of an n⁺-type silicon carbide substrate (semiconductor substrate of the first conductivity type) 1.

The n⁺-type silicon carbide substrate 1, for example, is a silicon carbide single crystal substrate doped with nitrogen (N). The n-type silicon carbide epitaxial layer 2 is a low-concentration n-type drift layer doped with, for example, nitrogen and having an impurity concentration lower than that of the n⁺-type silicon carbide substrate 1. At a surface on a first side of the n-type silicon carbide epitaxial layer 2, opposite a second side thereof facing the n⁺-type silicon carbide substrate 1, an n-type high-concentration region 6 may be provided. The n-type high-concentration region 6 is a high-concentration n-type drift layer having an impurity concentration lower than that of the n⁺-type silicon carbide substrate 1 and higher than that of the n-type silicon carbide epitaxial layer 2.

At a surface side of the n-type high-concentration region 6 (when the n-type high-concentration region 6 is not provided, the n-type silicon carbide epitaxial layer 2, hereinafter abbreviated as “(2)”), opposite a side thereof facing toward the n⁺-type silicon carbide substrate 1, a p-type base layer (second semiconductor layer of the second conductivity type) 3 is provided. Hereinafter, the n⁺-type silicon carbide substrate 1, the n-type silicon carbide epitaxial layer 2, and the p-type base layer 3 collectively are referred to as a silicon carbide semiconductor base.

As depicted in FIG. 2, at a second main surface (rear surface, i.e., a rear surface of the silicon carbide semiconductor base) of the n⁺-type silicon carbide substrate 1, a rear electrode (second electrode) 14 is provided. The rear electrode 14 configures a drain electrode. At a surface of the rear electrode 14, a drain electrode pad (not depicted) is provided.

At a first main surface side (side having the p-type base layer 3) of the silicon carbide semiconductor base, a striped trench structure is formed. In particular, a trench 18 penetrates through the p-type base layer 3 from a surface of the p-type base layer 3, on a first side (the first main surface side of the silicon carbide semiconductor base) thereof, opposite a second side thereof facing toward the n⁺-type silicon carbide substrate 1, and reaches the n-type high-concentration region 6 (2). Along an inner wall of the trench 18, a gate insulating film 9 is formed along a bottom and side walls of the trench 18, on the gate insulating film 9 in the trench 18, a gate electrode 10 having a striped shape is formed. The gate electrode 10 is insulated from the n-type high-concentration region 6 and the p-type base layer 3 by the gate insulating film 9. A portion of the gate electrode 10 protrudes from a top of the trench 18 toward the source electrode pad 15 described hereinafter.

In a surface layer on the surface side (the first main surface side of the silicon carbide semiconductor base) of the n-type high-concentration region 6 (2), opposite the side thereof facing toward the n⁺-type silicon carbide substrate 1, a first p⁺-type base region 4 is selectively provided. A second p⁺-type base region 5 is formed beneath the trench 18 and a width of the second p⁺-type base region 5 is greater than a width of the trench 18. The first p⁺-type base region 4 and the second p⁺-type base region 5, for example, are doped with aluminum.

A portion of the first p⁺-type base region 4 may extend toward the trench 18 to thereby be connected to the second p⁺-type base region 5. In this case, portions of the first p⁺-type base region 4 may have a planar layout in which the portions of the first p⁺-type base region 4 and the n-type high-concentration region 6 (2) are disposed to repeatedly alternate each other along a direction (hereinafter, second direction) y orthogonal to a direction (hereinafter, first direction) x along which the first p⁺-type base region 4 and the second p⁺-type base region 5 are arranged. For example, a structure in which the portions of the first p⁺-type base region 4 extend toward both trenches 18 in the first direction x to be connected with the second p⁺-type base regions 5 may be periodically disposed along the second direction y. A reason for this is that holes occurring when avalanche breakdown occurs at a junction portion between the second p⁺-type base region 5 and the n-type silicon carbide epitaxial layer 2 are efficiently migrated to a source electrode (first electrode) 13, whereby load on the gate insulating film 9 is reduced and reliability is increased.

In the p-type base layer 3, an n⁺-type source region (first semiconductor region of the first conductivity type) 7 is selectively provided on a base first main surface side. Further, a p⁺⁺-type contact region 8 may be provided. The n⁺-type source region 7 is in contact with the trench 18. Further, the n⁺-type source region 7 and the p⁺⁺-type contact region 8 are in contact with each other.

Further, the n-type high-concentration region 6 (2) is provided in a region sandwiched between the second p⁺-type base region 5 and the first p⁺-type base region 4 of a surface layer on a base first main surface side of the n-type silicon carbide epitaxial layer 2, and in a region sandwiched between the second p⁺-type base region 5 and the p-type base layer 3.

An interlayer insulating film 11 is provided at the first main surface side of the silicon carbide semiconductor base overall, so as to cover the gate electrode 10 embedded in the trench 18. The source electrode 13 is in contact with the n⁺-type source region 7 and the p-type base layer 3 via a contact hole opened in the interlayer insulating film 11, or is in contact with the n⁺-type source region 7 and the p⁺⁺-type contact region 8, when the p⁺⁺-type contact region 8 is provided. The source electrode 13, for example, is formed using a NiSi film. The contact hole opened in the interlayer insulating film 11 has a striped shape corresponding to a shape of the gate electrode 10. The source electrode 13 is electrically insulated from the gate electrode 10 by the interlayer insulating film 11. On the source electrode 13, the source electrode pad 15 is provided. The source electrode pad 15, for example, is formed by stacking a first TiN film 25, a first Ti film 26, a second TiN film 27, a second Ti film 28, and an Al alloy film 29. Between the source electrode 13 and the interlayer insulating film 11, for example, a barrier metal (not depicted) that prevents diffusion of metal atoms from the source electrode 13 toward the gate electrode 10 may be provided.

At an upper portion of the source electrode pad 15, a plating film 16 is selectively provided, and on an upper portion of the plating film 16, a solder 17 is selectively provided. In the solder 17, an external terminal electrode 19 that is a wiring member for leading out electric potential of the source electrode 13 to an external destination is provided. The external terminal electrode 19 has a needle-like pin shape and is joined in an upright state to the source electrode pad 15.

A portion of a surface of the source electrode pad 15 excluding the plating film 16 is covered by a first protective film 21. In particular, the first protective film 21 is provided so as to cover the source electrode pad 15, and the external terminal electrode 19 is joined at the opening of the first protective film 21, via the plating film 16 and the solder 17. A border between the plating film 16 and the first protective film 21 is covered by a second protective film 23. The first protective film 21 and the second protective film 23, for example, are polyimide films.

Further, as depicted in FIG. 2, in the gate electrode pad region 22a of the silicon carbide semiconductor device according to the embodiment, the n-type silicon carbide epitaxial layer 2 is deposited on the first main surface (front surface), for example, a (0001) plane (Si-face), of the n⁺-type silicon carbide substrate (semiconductor substrate of the first conductivity type) 1 and the p-type base layer 3 is provided in the n-type silicon carbide epitaxial layer 2. Further, beneath the p-type base layer 3, the first p⁺-type base region 4 of a same size as the p-type base layer 3 is provided. However, the first p⁺-type base region 4 is not required. Further, the p⁺⁺-type contact region 8 may be provided. The p⁺⁺-type contact region 8 is provided at the base first main surface side.

Further, on the p+⁺-type contact region 8 (when the p+⁺-type contact region 8 is not provided, the p-type base layer 3, hereinafter abbreviated as “(3)”), the interlayer insulating film 11 is provided and the source electrode pad 15 and the gate electrode pad 22 are provided separated from each other on the interlayer insulating film 11. The gate electrode pad 22 may be formed a part of the Al alloy film 29. The source electrode pad 15 is electrically connected to the p+⁺-type contact region 8 (3) via the opening of the interlayer insulating film 11. The gate electrode pad 22 is electrically connected to the gate electrode 10.

In the silicon carbide semiconductor device according to the first embodiment, a distance w1 from an end (contact area end) w1a located furthest from the gate electrode pad 22 of a contact area where the source electrode pad 15 and the p⁺⁺-type contact region 8 (3) of the gate electrode pad region 22a are in contact with each other, to an end (second semiconductor layer end) w1b located furthest from the gate electrode pad 22 of the p⁺⁺-type contact region 8 (3) is at least two times (w1/w22) greater than a width w2 of an overhanging portion of the interlayer insulating film 11 that is beyond the trench 18 and may be 10≤w1/w2≤20. The interlayer insulating film 11 extends over the trench and has overhanging portion that extends beyond the trench 18, and overhangs a part of the n⁺-type source region 7. The width of the overhanging portion of the interlayer insulating film 11 is a distance along a width (y-axis direction) direction of the trench 18, from the side wall of the trench 18 to the end of the interlayer insulating film 11.

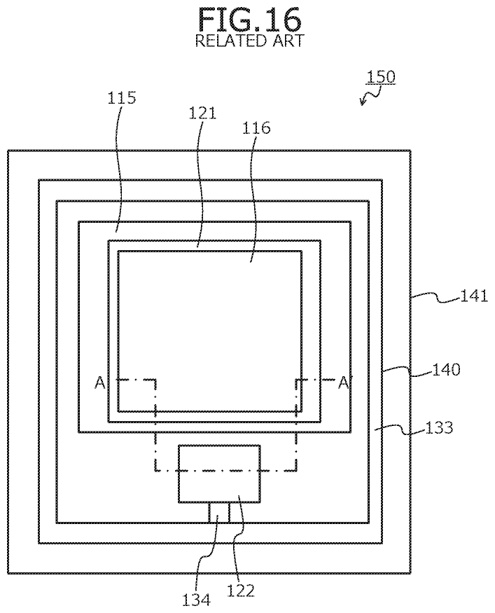

In the conventional silicon carbide semiconductor device, the distance w101 from a portion where the source electrode pad 115 and the p⁺⁺-type contact region 108 of the gate electrode pad region 122a are in contact with each other, to an end of the p⁺⁺-type contact region 108 is a width (w101≈w102, refer to FIG. 16) that is about a same as a width w102 of an overhanging portion of the interlayer insulating film 111 at the trench 118. Therefore, in the conventional silicon carbide semiconductor device, a distance (path A in FIG. 17) between a corner of the p-type base layer 103 and a contact hole portion of the gate electrode pad region 122a, and a distance (path B of FIG. 17) between the contact hole of the gate electrode pad region 122a and a portion of the p-type base layer 103 directly beneath the contact hole do not significantly differ in length. Therefore, current during reverse recovery flows along path A and path B, and carriers concentrate at the corner of the p-type base layer 103.

On the other hand, in the silicon carbide semiconductor device according to the first embodiment, the distance w1 from the portion where the p+⁺-type contact region 8 (3) and the source electrode pad 15 are in contact with each other, to the end of the p⁺⁺-type contact region 8 (3) is greater than the width w2 of the overhanging portion of the interlayer insulating film 11 that extends beyond the trench 18. Therefore, a distance (path A in FIG. 2) between a corner of the p-type base layer 3 and a contact hole portion of the gate electrode pad region 22a is greater than a distance (path B in FIG. 2) between the contact hole of the gate electrode pad region 22a and a portion of the p-type base layer 3 directly beneath the contact hole. Therefore, path A has a larger resistance and more current during reverse recovery flows along path B, whereby carrier concentration at the corner of the p-type base layer 3 may be reduced. As a result, interrupting current during switching increases and decreases in current capacity during reverse recovery may be prevented.

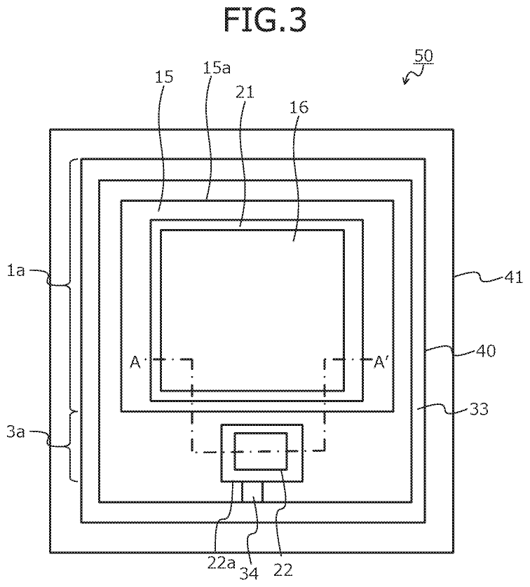

FIG. 3 is a top view of another structure of the silicon carbide semiconductor device according to the first embodiment. As depicted in FIG. 3, gate resistance 34 between the gate electrode pad 22 and a gate poly-silicon electrode 33 is provided. Even when the silicon carbide semiconductor elements are used connected in parallel without connection of an external chip resistor and there is variation in characteristics between the silicon carbide semiconductor elements, uniform operation of the elements may be achieved due to the gate resistance 34.

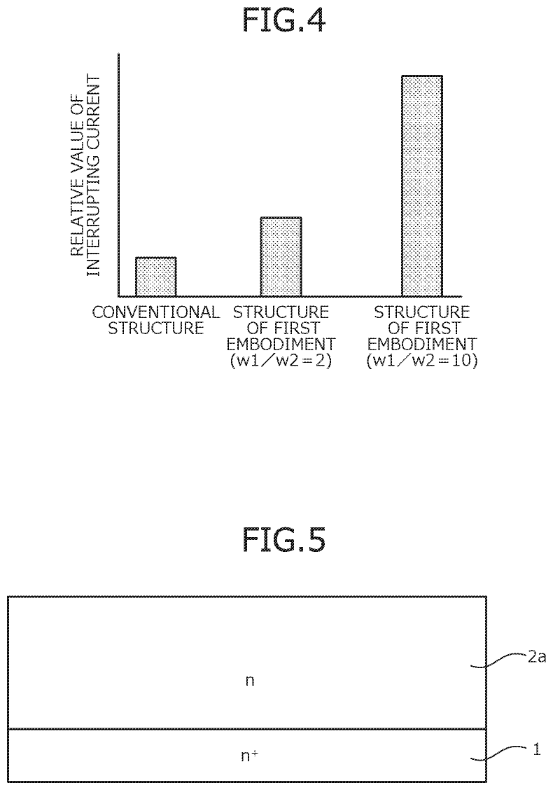

FIG. 4 is a graph depicting relative values of interrupting current of the conventional silicon carbide semiconductor device and the silicon carbide semiconductor device according to the first embodiment. In FIG. 4, a vertical axis represents relative values of interrupting current. Cases of w1/w2=2 and w1/w2=10 in the silicon carbide semiconductor device according to the first embodiment are depicted. As depicted in FIG. 4, in the case of w1/w2=2 in the silicon carbide semiconductor device according to the first embodiment, interrupting current increases to a greater extent than in the conventional silicon carbide semiconductor device. Further, in the case of w1/w2=10 in the silicon carbide semiconductor device according to the first embodiment, interrupting current increases to a greater extent than in the case of w1/w2=2 in the silicon carbide semiconductor device according to the first embodiment.

A method of manufacturing the silicon carbide semiconductor device according the first embodiment will be described. FIGS. 5, 6, 7, 8, 9, and 10 are cross-sectional views of the silicon carbide semiconductor device according to the first embodiment during manufacture.

First, the n⁺-type silicon carbide substrate 1 containing silicon carbide of an n-type is prepared. Then, on the first main surface of the n⁺-type silicon carbide substrate 1, a first n-type silicon carbide epitaxial layer 2a containing silicon carbide is formed by epitaxial growth to have a thickness of, for example, about 30 μm while an n-type impurity, for example, nitrogen atoms, is doped. The first n-type silicon carbide epitaxial layer 2a forms the n-type silicon carbide epitaxial layer 2. The state up to here is depicted in FIG. 5.

Next, on the surface of the first n-type silicon carbide epitaxial layer 2a, an ion implantation mask provided with a predetermined opening by a photolithography technique, for example, is formed using an oxide film. Then, a p-type impurity such as aluminum is implanted in the opening of the oxide film, thereby forming a lower first p⁺-type base region 4a at a depth of about 0.5 μm. Concurrently with the lower first p⁺-type base region 4a, the second p⁺-type base region 5 forming the bottom of the trench 18 may be formed so that a distance between the lower first p⁺-type base region 4a and the second p⁺-type base region 5 that are adjacent to each other is about 1.5 μm. An impurity concentration of the lower first p⁺-type base region 4a and the second p⁺-type base region 5 is set to be, for example, about 5×10¹⁸/cm³.

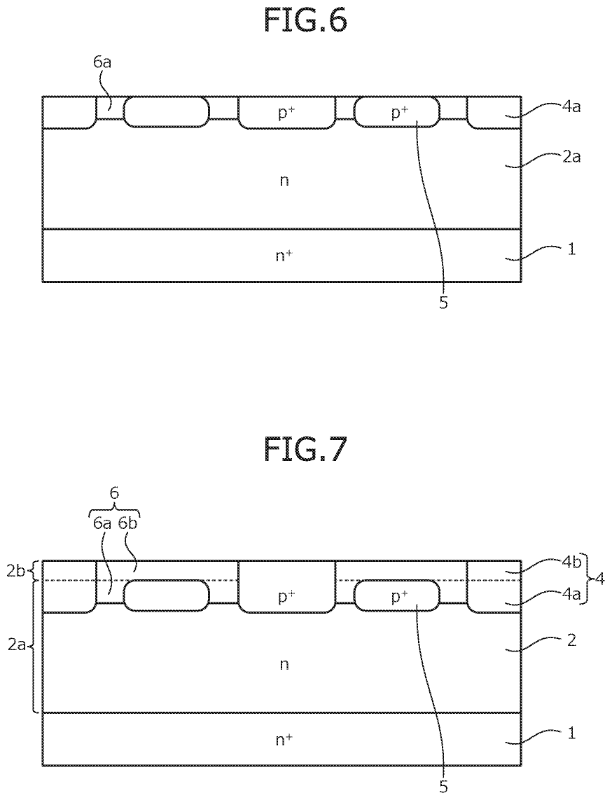

Next, a portion of the ion implantation mask is removed, an n-type impurity such as nitrogen is ion implanted in the opening, thereby providing at a portion of a surface region of the first n-type silicon carbide epitaxial layer 2a, a lower n-type high-concentration region 6a of a depth of, for example, about 0.5 μm. An impurity concentration of the lower n-type high-concentration region 6a is set to be, for example, about 1×10¹⁷/cm³. The state up to here is depicted in FIG. 6.

Next, on the surface of the first n-type silicon carbide epitaxial layer 2a, a second n-type silicon carbide epitaxial layer 2b doped with an n-type impurity such as nitrogen is formed to have a thickness of about 0.5 μm. An impurity concentration of the second n-type silicon carbide epitaxial layer 2b is set to be about 3×10¹⁵/cm³. Hereinafter, the first n-type silicon carbide epitaxial layer 2a and the second n-type silicon carbide epitaxial layer 2b collectively form the n-type silicon carbide epitaxial layer 2.

Next, on the surface of the second n-type silicon carbide epitaxial layer 2b, an ion implantation mask provided with a predetermined opening by photolithography is formed using, for example, an oxide film. Then, a p-type impurity such as aluminum is implanted in the opening of the oxide film, thereby forming an upper first p⁺-type base region 4b so as to overlap the lower first p⁺-type base region 4a and have a thickness of about 0.5 μm. The lower first p⁺-type base region 4a and the upper first p⁺-type base region 4b form a continuous region and become the first p⁺-type base region 4. An impurity concentration of the upper first p⁺-type base region 4b may be set to be, for example, about 5×10¹⁸/cm³.

Next, a portion of the ion implantation mask is removed, an n-type impurity such as nitrogen is ion implanted in the opening, thereby providing at a portion of a surface region of the second n-type silicon carbide epitaxial layer 2b, an upper n-type high-concentration region 6b of a depth of, for example, about 0.5 μm. An impurity concentration of the upper n-type high-concentration region 6b is set to be, for example, about 1×10¹⁷/cm³. The upper n-type high-concentration region 6b and the lower n-type high-concentration region 6a are formed so as to be in contact with each other at least at one portion, whereby the n-type high-concentration region 6 is formed. However, the n-type high-concentration region 6 may be formed at the substrate surface overall or may not be formed. The state up to here is depicted in FIG. 7.

Next, on the surface of the n-type silicon carbide epitaxial layer 2, the p-type base layer 3 doped with a p-type impurity such as aluminum is formed to have a thickness of about 1.3 μm. An impurity concentration of the p-type base layer 3 is set to be about 4×10¹⁷/cm³.

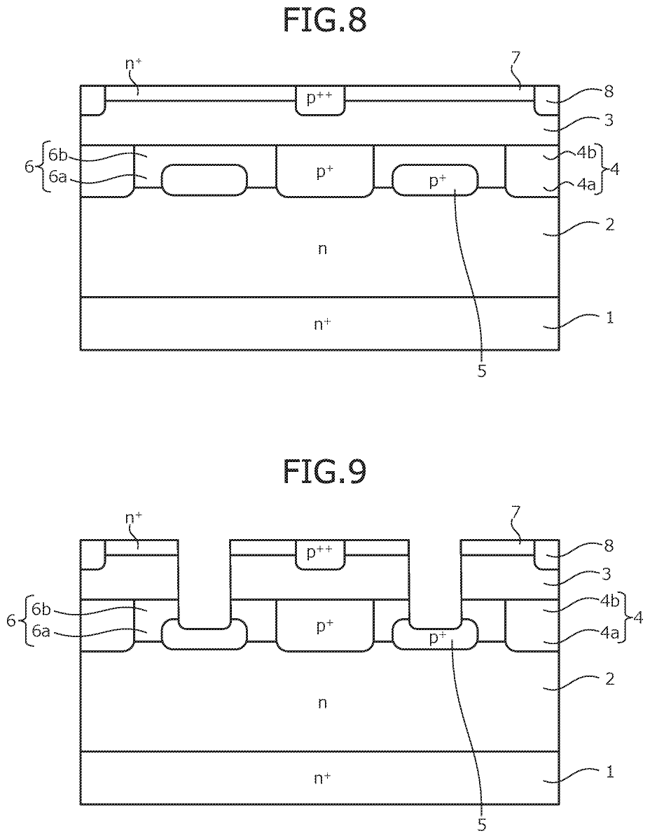

Next, on the surface of the p-type base layer 3, an ion implantation mask provided with a predetermined opening by photolithography is formed using, for example, an oxide mask. An n-type impurity such as phosphorus (P) is ion implanted in the opening, thereby forming the n⁺-type source region 7 at a portion of the surface of the p-type base layer 3. An impurity concentration of the n⁺-type source region 7 is set to be higher than the impurity concentration of the p-type base layer 3. Next, the ion implantation mask used in forming the n⁺-type source region 7 is removed and by a similar method, an ion implantation mask provided with a predetermined opening may be formed, a p-type impurity such as aluminum may be ion implanted at a portion of the surface of the p-type base layer 3, whereby the p⁺⁺-type contact region 8 may be formed. An impurity concentration of the p⁺⁺-type contact region 8 is set to be higher than the impurity concentration of the p-type base layer 3. The state up to here is depicted in FIG. 8.

By the processes up to here, the n-type silicon carbide epitaxial layer 2 is deposited in the gate electrode pad region 22a, and the p⁺⁺-type contact region 8 and the p-type base layer 3 are formed in the n-type silicon carbide epitaxial layer 2.

Next, an activation process of the first p⁺-type base region 4, the second p⁺-type base region 5, the n⁺-type source region 7, and the p+⁺-type contact region 8 is implemented by performing a heat treatment (annealing) under an inert gas atmosphere at a temperature of about 1700 degrees C. As described above, ion implanted regions may be activated collectively by a single session of the heat treatment or each may be activated by performing the heat treatment each time ion implantation is performed.

Next, on the surface of the p-type base layer 3, a trench formation mask provided with a predetermined opening by photolithography is formed using, for example, an oxide film. Next, the trench 18 is formed by dry etching and penetrates through the p-type base layer 3 and reaches the n-type high-concentration region 6 (2). The bottom of the trench 18 may reach the second p⁺-type base region 5 formed in the n-type high-concentration region 6 (2). Next, the trench formation mask is removed. The state up to here is depicted in FIG. 9.

Next, the gate insulating film 9 is formed along the surface of the n⁺-type source region 7, the bottom and the side walls of the trench 18. The gate insulating film 9 may be formed by thermal oxidation at a temperature of about 1000 degrees C. in an oxygen atmosphere. Further, the gate insulating film 9 may be formed by a deposition method by a chemical reaction such as that for a high temperature oxide (HTO).

Next, on the gate insulating film 9, for example, a polycrystalline silicon layer doped with phosphorus atoms is provided. The polycrystalline silicon layer may be formed so as to be embedded in the trench 18. The polycrystalline silicon layer is patterned by photolithography and is left in the trench 18, whereby the gate electrode 10 is formed.

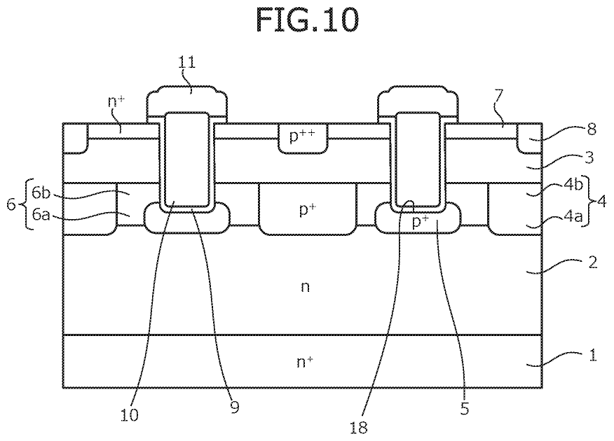

Next, for example, a phosphate glass is deposited so as to cover the gate insulating film 9 and the gate electrode 10 and have a thickness of about 1 μm, whereby the interlayer insulating film 11 is formed. Next, a barrier metal (not depicted) containing titanium (Ti) or titanium nitride (TiN) may be formed so as to cover the interlayer insulating film 11. The interlayer insulating film 11 and the gate insulating film 9 are patterned by photolithography, whereby a contact hole is formed exposing the n⁺-type source region 7 and the p⁺⁺-type contact region 8. Thereafter, a heat treatment (reflow) is performed, whereby the interlayer insulating film 11 is planarized. The state up to here is depicted in FIG. 10.

Next, in the contact hole and on the interlayer insulating film 11, a conductive film forming the source electrode 13 is provided. The conductive film is selectively removed, leaving the source electrode 13 only in contact hole and contacting the source electrode 13 with the n⁺-type source region 7 and the p⁺⁺-type contact region 8. Next, the source electrode 13 is selectively removed, excluding that in the contact hole.

Next, for example, by a sputtering method, on the source electrode 13 on the front surface of the silicon carbide semiconductor base and upper portion of the interlayer insulating film 11, an electrode pad forming the source electrode pad 15 is deposited. For example, by a sputtering method, the first TiN film 25, the first Ti film 26, the second TiN film 27, and the second Ti film 28 are stacked, and the Al alloy film 29 is further formed to have a thickness of, for example, about 5 μm. The Al alloy film 29 may be an Al film. The Al alloy film 29 is, for example, an Al—Si film or an Al—Si—Cu film. The conductive film is patterned by photolithography and left in the active region 40 of an element overall, whereby the source electrode pad 15 is formed. A thickness of a portion of the electrode pad on the interlayer insulating film 11 may be, for example, about 5 μm. The electrode pad, for example, may be formed using aluminum (Al—Si) containing silicon at a ratio of 1%. Next, the source electrode pad 15 is selectively removed. Here, the distance w1 from the portion where the source electrode pad 15 and the p⁺⁺-type contact region 8 (3) in the gate electrode pad region 22a are in contact with each other, to the end of the p⁺⁺-type contact region 8 (3) is at least two times (w1/w22) greater than the width w2 of the overhanging portion of the interlayer insulating film 11 that extends beyond the trench 18 and may be formed to be 10≤w1/w2≤20.

Next, a polyimide film is formed so as to cover the source electrode pad 15. Next, the polyimide film is selectively removed by photolithography and etching, thereby forming the first protective films 21 respectively covering the source electrode pads 15 and opening the first protective films 21.

Next, at an upper portion of the source electrode pad 15, the plating film 16 is selectively formed, and the second protective film 23 covering each border between the plating film 16 and the first protective film 21 is formed. Next, the external terminal electrode 19 is formed at the plating film 16 via the solder 17.

Next, on the second main surface of the n⁺-type silicon carbide substrate 1, the rear electrode 14 containing nickel, etc. is provided. Thereafter, a heat treatment is performed in an inert gas atmosphere at a temperature of about 1000 degrees C., whereby the rear electrode 14 forming an ohmic contact with the n⁺-type silicon carbide substrate 1 is formed. In this manner, the silicon carbide semiconductor device depicted in FIGS. 1 to 3 is completed.

As described above, according to the silicon carbide semiconductor device according to the first embodiment, the distance from a contact portion between the source electrode pad and the p⁺⁺-type contact region in the gate electrode pad region to the end of the p⁺⁺-type contact region is at least two times greater than the width of the overhanging portion of the interlayer insulating film beyond the trench. As a result, current flowing along the path of the corner of the p-type base layer and the contact hole portion of the gate electrode pad region is reduced. Therefore, carrier concentration at the corner of the p-type base layer may be reduced, interrupting current during switching increases, and decreases in the current capacity during reverse recovery may be prevented.

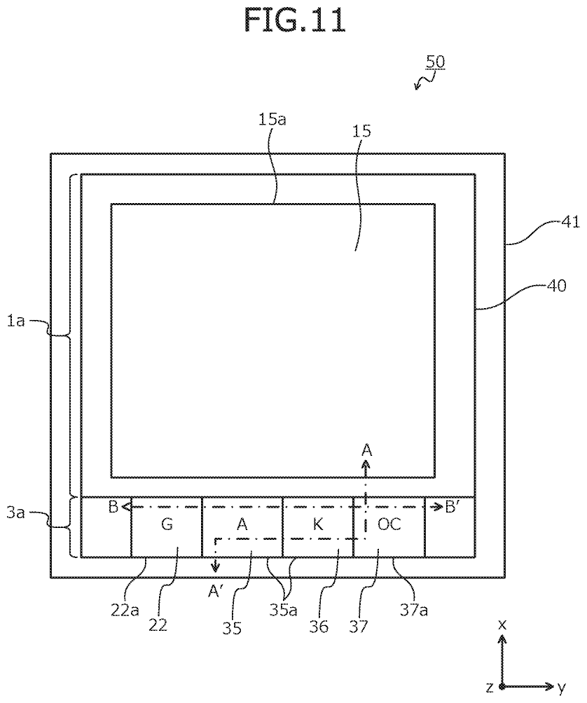

FIG. 11 is a top view of a structure of the silicon carbide semiconductor device according to a second embodiment. The silicon carbide semiconductor device according to the second embodiment differs from the silicon carbide semiconductor device according to the first embodiment in that in the active region 40, a high-function region 3a is provided in contact with the edge termination region 41. The high-function region 3a has, for example, a substantially rectangular planar shape. In the high-function region 3a, high-function regions such as a current sensing portion 37a, a temperature sensing portion 35a, an over-voltage protecting portion (not depicted) and an arithmetic circuit portion (not depicted) are provided. In FIG. 11, while the current sensing portion 37a and the temperature sensing portion 35a are depicted as a high-function region, a high-function region other than the current sensing portion 37a and the temperature sensing portion 35a may be disposed as the high-function region 3a.

The current sensing portion 37a has a function of detecting overcurrent (OC) flowing in the main semiconductor element 15a. The current sensing portion 37a is a vertical MOSFET that includes about several unit cells of a same configuration as the main semiconductor element 15a. The temperature sensing portion 35a has a function of using diode temperature characteristics to detect a temperature of the main semiconductor element 15a. The over-voltage protecting portion is, for example, a diode that protects the main semiconductor element 15a from overvoltage (OV) such as surges.

Further, in the high-function region 3a, on the front surface of the semiconductor substrate, along the border between the active region 40 and the edge termination region 41 and separated from the source electrode pad 15 and the edge termination region 41, an OC pad 37 of the current sensing portion 37a, an anode electrode pad 35 and a cathode electrode pad 36 of the temperature sensing portion 35a, the gate electrode pad 22 of the gate electrode pad region 22a are provided. These electrode pads have, for example, a substantially rectangular planar shape. Further, these electrode pads may be provided separated from each other.

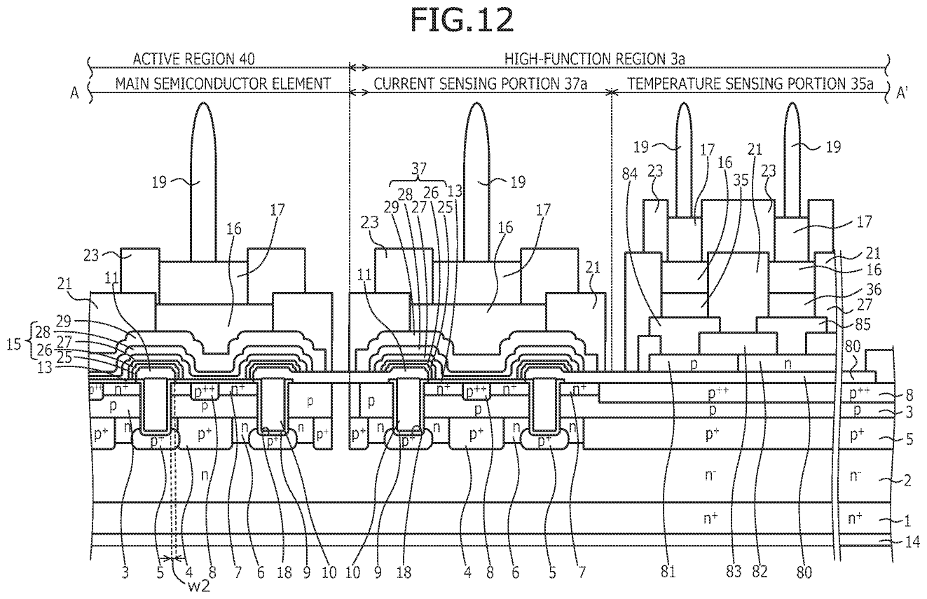

FIG. 12 is a cross-sectional view of a structure of a portion of the silicon carbide semiconductor device according to the second embodiment, along cutting line A-A′ in FIG. 11. The structure of the active region 40 is similar to that in the first embodiment and therefore, description thereof is omitted hereinafter. Further, the structure of the current sensing portion 37a is similar to that in the active region 40 and therefore, description thereof is omitted hereinafter.

As depicted in FIG. 12, in the temperature sensing portion 35a of the silicon carbide semiconductor device according to the second embodiment, at the first main surface (front surface), for example, (0001) plane (Si-face), of the n⁺-type silicon carbide substrate (semiconductor substrate of the first conductivity type) 1, the n-type silicon carbide epitaxial layer 2 is deposited and on the base first main surface side of the n-type silicon carbide epitaxial layer 2, the second p⁺-type base region 5 and the p-type base layer 3 are provided. In the p-type base layer 3, the p+⁺-type contact region 8 may be provided on the base first main surface side.

Further, a field insulating film 80 is provided on the p+⁺-type contact region 8 (3), and a p-type poly-silicon layer 81 and an n-type poly-silicon layer 82 are provided on the field insulating film 80. The p-type poly-silicon layer 81 and the n-type poly-silicon layer 82 are a poly-silicon diode formed by a pn junction. Instead of the p-type poly-silicon layer 81 and the n-type poly-silicon layer 82, a diffusion diode formed by a pn junction between a p-type diffusion region and an n-type diffusion region may be used as the temperature sensing portion 35a. In this case, for example, in an n-type separation region (not depicted) selectively formed in the second p⁺-type base region 5, the p-type diffusion region and the n-type diffusion region configuring the diffusion diode may be selectively formed.

The anode electrode pad 35 is electrically connected to the p-type poly-silicon layer 81, via an anode electrode 84. The cathode electrode pad 36 is electrically connected to the n-type poly-silicon layer 82, via a cathode electrode 85. The anode electrode pad 35 and the cathode electrode pad 36, similarly to the source electrode pad 15 of the main semiconductor element 15a, are joined to the external terminal electrode 19, via the plating film 16 and the solder 17, respectively, and are protected by the first protective film 21 and the second protective film 23.

As depicted in FIG. 12, at the second main surface (rear surface, i.e., the rear surface of the silicon carbide semiconductor base), of the n⁺-type silicon carbide substrate 1, the rear electrode 14 is provided. The rear electrode 14 configures a drain electrode. At the surface of the rear electrode 14, the drain electrode pad (not depicted) is provided.

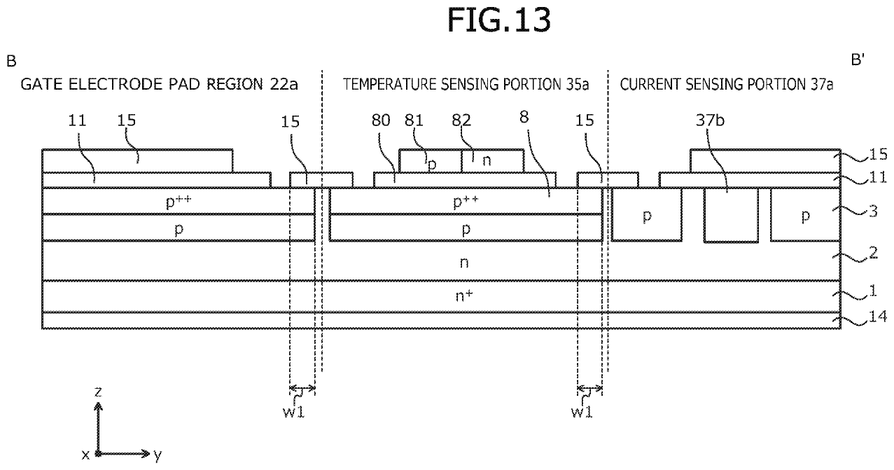

FIG. 13 is a cross-sectional view of a structure of a portion of the silicon carbide semiconductor device according to the second embodiment, along cutting line B-B′ in FIG. 11. In FIG. 13, the structure above (positive direction along the z-axis) the p⁺⁺-type contact region 8 (3) is not shown. As depicted in FIG. 13, at the gate electrode pad region 22a, the temperature sensing portion 35a, and the current sensing portion 37a, the p-type base layer 3 is provided in the n-type silicon carbide epitaxial layer 2. The p-type base layer 3 of the gate electrode pad region 22a, the temperature sensing portion 35a, and the current sensing portion 37a is the p-type base layer 3 of the main semiconductor element 15a and in the current sensing portion 37a, an active region 37b of the current sensing portion is provided between the p-type base layers 3.

As depicted in FIG. 13, the p-type base layer (second semiconductor layer regions) 3 of the gate electrode pad region 22a, the temperature sensing portion 35a, and the current sensing portion 37a may be separated from the p-type base layer (second semiconductor layer regions) 3 of the main semiconductor element 15a by a predetermined interval. In this manner, a built-in diode configured by the n-type silicon carbide epitaxial layer 2 and the p-type base layer 3 of the gate electrode pad region 22a, the temperature sensing portion 35a, and the current sensing portion 37a does not operate, and when the current sensing portion 37a is at adjacent portions, minority carriers are prevented from going around into the current sensing portion 37a.

Further, the p-type base layer 3 of the temperature sensing portion 35a and the current sensing portion 37a may be continuous. In the active region 37b of the current sensing portion, when minority carriers of the built-in diode formed by the p-type region and the n-type region of adjacent portions go around and enter, the actual current density during switching increases and the semiconductor device is easily destroyed.

As depicted in FIGS. 12 and 13, in the silicon carbide semiconductor device according to the second embodiment, in the gate electrode pad region 22a, the temperature sensing portion 35a and the current sensing portion 37a, the distance w1 from the contact portion between the p⁺⁺-type contact region 8 (3) and the source electrode pad 15 to the end of the p⁺⁺-type contact region 8 (3) (a length of the contact portion in a plan view) is at least two times (w1/w22) the width w2 of the overhanging portion of the interlayer insulating film 11 beyond the trench 18 and may be 10≤w1/w2≤20. Therefore, carrier concentration at the corner of the p-type base layer 3 of the current sensing portion 37a, the temperature sensing portion 35a, and the gate electrode pad region 22a may be reduced. As a result, interrupting current during switching increases and decreases in the current capacity during reverse recovery may be prevented.

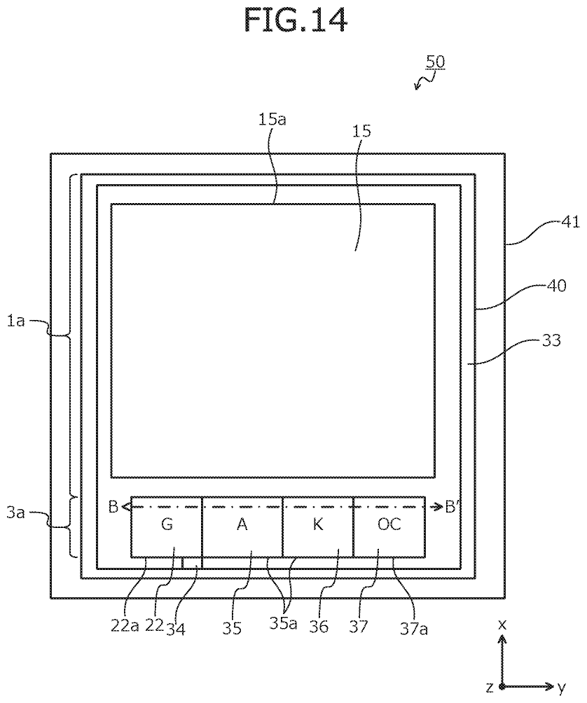

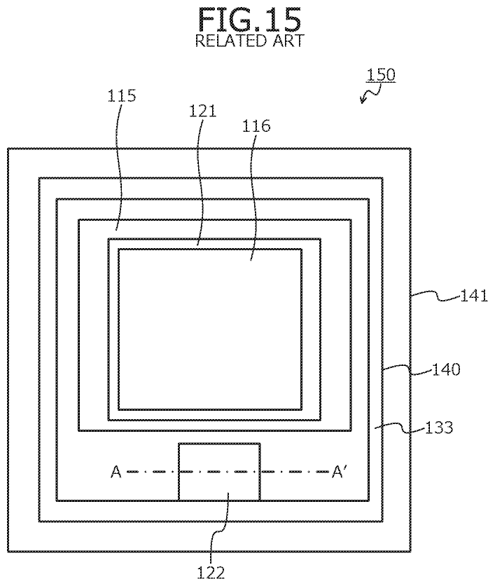

FIG. 14 is a top view of another structure of the silicon carbide semiconductor device according to the second embodiment. As depicted in FIG. 14, the gate resistance 34 is provided between the gate electrode pad 22 and the gate poly-silicon electrode 33. In the structure depicted in FIG. 14 as well, similarly to that in FIG. 12, in the gate electrode pad region 22a, the temperature sensing portion 35a, and the current sensing portion 37a, the distance w1 from the contact portion between the p⁺⁺-type contact region 8 (3) and the source electrode pad 15 to the end of the p⁺⁺-type contact region 8 (3) is at least two times (w1/w22) the width w2 of the overhanging portion of the interlayer insulating film 11 beyond the trench 18 and may be 10≤w1/w2≤20.

In the second embodiment, a method of manufacturing the active region 40 is similar to that in the first embodiment and therefore, description thereof is omitted hereinafter. Further, a method of manufacturing the current sensing portion 37a is similar to the method of manufacturing the active region 40 and therefore, description thereof is omitted hereinafter.

The temperature sensing portion 35a is formed as follows. Before formation of the electrode pads, in the temperature sensing portion 35a, on the field insulating film 80, by a general method, the p-type poly-silicon layer 81, the n-type poly-silicon layer 82, the interlayer insulating film 11, the anode electrode 84, and the cathode electrode 85 are formed. Here, the distance w1 from the contact portion between the source electrode pad 15 and the p⁺⁺-type contact region 8 (3) of the temperature sensing portion 35a to the end of the p⁺⁺-type contact region 8 (3) is at least two times (w1/w22) the width w2 of the overhanging portion of 2 the interlayer insulating film 11 beyond the trench 18 and may be 10≤w1/w2≤20.

Further, the p-type poly-silicon layer 81 and the n-type poly-silicon layer 82 of the temperature sensing portion 35a, for example, may be formed concurrently with the gate electrode 10 in the main semiconductor element 15a and the current sensing portion 37a. The field insulating film 80 may be a portion of the interlayer insulating film 11 in the current sensing portion 37a and the main semiconductor element 15a. In this case, the p-type poly-silicon layer 81 and the n-type poly-silicon layer 82 in the temperature sensing portion 35a is formed after formation of the interlayer insulating film 11 in the current sensing portion 37a and the main semiconductor element 15a.

Next, the anode electrode pad 35 and the cathode electrode pad 36 in contact with the anode electrode 84 and the cathode electrode 85, respectively, are formed. The anode electrode pad 35 and the cathode electrode pad 36 may be formed as the source electrode pad 15 and may have a stacked structure similar to that of the source electrode pad 15.

Next, a polyimide film is formed so as to cover the anode electrode pad 35 and the cathode electrode pad 36. Next, the polyimide film is selectively removed by photolithography and etching, thereby forming the first protective films 21 covering the anode electrode pad 35 and the cathode electrode pad 36, respectively, and opening the first protective films 21.

Next, the plating film 16 is selectively formed at an upper portion of the cathode electrode pad 36 and the anode electrode pad 35, and the second protective film 23 is formed so as to cover the borders between the plating film 16 and the first protective film 21. Next, the external terminal electrode 19 is formed in the plating film 16, via the solder 17. In this manner, the temperature sensing portion 35a is formed.

As described above, according to the silicon carbide semiconductor device according to the second embodiment, in the gate electrode pad region, the temperature sensing portion, and the current sensing portion, the distance from a contact portion between the p⁺⁺-type contact region and the source electrode pad, to the end of the p⁺⁺-type contact region is greater than the width of the portion of the interlayer insulating film extending beyondthe trench. As a result, current flowing along the path between the corner of the p-type base layer and the contact hole portion of the gate electrode pad region is reduced. Therefore, carrier concentration at the corner of the p-type base layer may be reduced and the interrupting current during switching increases, enabling decreases in the current capacity during reverse recovery to be prevented.

In the invention above, while a case in which a main surface of a silicon carbide substrate containing silicon carbide is a (0001) plane and a MOS is configured on the (0001) plane is described as an example, without limitation hereto, various changes related to the wide bandgap semiconductor, plane orientation of the substrate main surface, etc. are possible.

Further, in the embodiments of the invention described above, while a trench MOSFET is described as an example, without limitation hereto, application is further possible with respect to semiconductor devices of various types of configurations such as MOS semiconductor devices like planar MOSFETs, IGBTs, etc. Further, in the embodiments of the invention described above, while a case in which silicon carbide is used as a wide bandgap semiconductor is described as an example, similar effects are obtained when a wide bandgap semiconductor other than silicon carbide such as gallium nitride (GaN) is used. Further, in the embodiments, while the first conductivity type is assumed to be an n-type and the second conductivity type is assumed to be a p-type, the present invention is similarly implemented when the first conductivity type is a p-type and the second conductivity type is an n-type.

According to the invention described above, the distance from a contact portion between the source electrode pad and the p-type base layer (second semiconductor layer of the second conductivity type) of the gate electrode pad region, to the end of the second semiconductor layer is at least two times greater than the width of the overhanging portion of the interlayer insulating film beyond the trench. As a result, current flowing on a path between the corner of the p-type base layer and the contact hole portion of the gate electrode pad region decreases. Therefore, carrier concentration at the corner of the p-type base layer may be reduced and interrupting current during switching increases, enabling decreases in the current capacity during reverse recovery to be prevented.

The semiconductor device and the method of manufacturing a semiconductor device according to the present invention achieve an effect in that decreases in the current capacity during reverse recovery of the PN diode built into the semiconductor device may be prevented.

As described above, the semiconductor device and the method of manufacturing a semiconductor device according to the present invention are useful for high-voltage semiconductor devices used in power converting equipment and in power source devices such as in various industrial machines.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
an active region through which a main current passes during an ON state, the active region being configured by a MOS structure, the MOS structure including:
a semiconductor substrate of a first conductivity type, having a front surface and a rear surface opposite to the front surface;
a first semiconductor layer of the first conductivity type, provided on the front surface of the semiconductor substrate, the first semiconductor layer having a first side facing the semiconductor substrate and a second side opposite to the first side, an impurity concentration of the first semiconductor layer being lower than an impurity concentration of the semiconductor substrate;
a second semiconductor layer of a second conductivity type, provided at a surface on the second side of the first semiconductor layer, the second semiconductor layer having a first side facing the semiconductor substrate and a second side opposite to the first side;
a first semiconductor region of the first conductivity type, selectively provided in a surface layer on the second side of the second semiconductor layer;
a trench that penetrates the first semiconductor region and the second semiconductor layer, and reaches the first semiconductor layer;
a gate electrode provided in the trench, via a gate insulating film;
an interlayer insulating film provided on the gate electrode, the interlayer insulating film having an overhanging portion overhanging a part of the second semiconductor layer beyond the trench;
a first electrode provided on a surface of the second semiconductor layer and a surface of the first semiconductor region;
a first electrode pad provided on a surface of the first electrode and being electrically connected to the first electrode; and
a second electrode provided on the rear surface of the semiconductor substrate; and
a gate electrode pad region including:
the semiconductor substrate;
the first semiconductor layer;
the second semiconductor layer;
the first electrode pad selectively provided on a surface of the second semiconductor layer;
the interlayer insulating film selectively provided on a surface of the second semiconductor layer; and
a gate electrode pad electrically connected to the gate electrode, the gate electrode pad being selectively provided at a surface on the second side of the second semiconductor layer, via the interlayer insulating film, wherein
in the gate electrode pad region, a distance from a contact area end of a contact area where the first electrode pad and the second semiconductor layer contact each other, to a second semiconductor layer end of the second semiconductor layer in a plan view of the semiconductor device is at least two times a width of the overhanging portion of the interlayer insulating film, the contact area end being an end located furthest in the contact area from the gate electrode pad, the second semiconductor layer end being an end located furthest in the second semiconductor layer from the gate electrode pad.

2. The semiconductor device according to claim 1, wherein the distance from the contact area end to the second semiconductor layer end is ten to twenty times the width of the overhanging portion of the interlayer insulating film.

3. The semiconductor device according to claim 1, wherein the second semiconductor layer includes a plurality of second semiconductor layer regions, one of the second semiconductor regions being the second semiconductor layer of the active region, the semiconductor device further comprising:
a current detection region configured by the MOS structure and sharing the semiconductor substrate and the first semiconductor layer with the active region, the current detection region including another one of the second semiconductor layer regions disposed separated from the one of the second semiconductor layer regions of the active region by a first predetermined interval; and
a temperature detection region sharing the semiconductor substrate and the first semiconductor layer with the active region, the temperature detection region including yet another one of the second semiconductor layer regions disposed separated from the one of the second semiconductor layer regions of the active region by a second predetermined interval, wherein
in the current detection region and in the temperature detection region, each length of a contact area where the first electrode pad and the second semiconductor layer contact each other in the plan view is at least two times a width of the overhanging portion of the interlayer insulating film.

4. The semiconductor device according to claim 3, wherein
in the current detection region and in the temperature detection region, said each length of the contact area is at least equal to but less than twenty times the width of the overhanging portion of the interlayer insulating film.

5. A method of manufacturing a semiconductor device having an active region having a MOS structure through which a main current passes during an ON state and a gate electrode pad region, the method comprising:
forming a first semiconductor layer of a first conductivity type on a semiconductor substrate of the first conductivity type, the semiconductor substrate having a front surface and a rear surface opposite to the front surface, the first semiconductor layer having a first side facing the semiconductor substrate and a second side opposite to the first side, an impurity concentration of the first semiconductor layer being lower than an impurity concentration of the semiconductor substrate;
forming a second semiconductor layer of a second conductivity type at a surface on the second side of the first semiconductor layer, the second semiconductor layer having a first side facing the semiconductor substrate and a second side opposite to the first side;
selectively forming a first semiconductor region of the first conductivity type in a surface layer on the second side of the second semiconductor layer;
forming a trench that penetrates the first semiconductor region and the second semiconductor layer, and reaches the first semiconductor layer;
forming a gate electrode in the trench, via a gate insulating film;
forming on the gate electrode an interlayer insulating film to have an overhanging portion overhanging a part of the second semiconductor layer beyond the trench;
forming a first electrode on a surface of the second semiconductor layer and a surface of the first semiconductor region;
forming a first electrode pad on a surface of the first electrode and a surface of the second semiconductor layer, the first electrode pad being electrically connected to the first electrode;
forming a second electrode on the rear surface of the semiconductor substrate; and
selectively forming a gate electrode pad at a surface on the second side of the second semiconductor layer, via the interlayer insulating film, the gate electrode pad electrically connected to the gate electrode, wherein
in the gate electrode pad region, a distance from a contact area end of a contact area where the first electrode pad and the second semiconductor layer contact each other, to a second semiconductor layer end of the second semiconductor layer in a plan view of the semiconductor device is at least two times a width of the overhanging portion of the interlayer insulating film, the contact area end being an end located furthest in the contact area from the gate electrode pad, the second semiconductor layer end being an end located furthest in the second semiconductor layer from the gate electrode pad.
